(19) United States
(12) Patent Application Publication
(10) Pub. No.: US 2014/0148009 A1
(43) Pub. Date: May 29, 2014

(54) Forming a Substantially Uniform Wing Height Among Elements in a Charge Trap Semiconductor Device

(71) Applicant: SPANSION LLC, Sunnyvale, CA (US)

(72) Inventors: Angela Tai Hui, Fremont, CA (US); David Matsumoto, San Jose, CA (US); Tung-sheng Chen, Cupertino, CA (US)

(73) Assignee: Spansion LLC, Sunnyvale, CA (US)

(21) Appl. No.: 13/685,222

(22) Filed: Nov. 26, 2012

(51) Int. Cl. H01L 21/306

(52) U.S. Cl. CPC H01L 21/30604
USPC 438/694; 156/345.51

(57) ABSTRACT

During formation of a charge trap separation in a semiconductor device, an organic material is formed over a plurality of cells. This organic material is selectively removed in order to create a flat upper surface. An etching process is performed to remove the organic material as well as a charge trap layer formed over the plurality of cells, thereby exposing underlying first oxide layers in each of the cells and forming charge trap separation. Further, because of the selective removal step, the etch results in substantially uniform wing heights among the separated cells.

### BACKGROUND

1. Technical Field

The disclosure generally relates to forming elements in a semiconductor device, and specifically to forming substantially uniform wing heights among elements of a charge trap semiconductor device.

2. Related Art

Charge trap semiconductors have become commercially viable for use in flash memory devices. Charge trap semiconductor configurations provide significant advantages over other configurations by allowing multiple bits to be stored in each individual cell. However, due to conventional manufacturing difficulties, charge trap semiconductor devices often contain variations that can cause errors or other performance issues.

FIG. 1A illustrates an exemplary semiconductor device 100 at an early processing stage. In FIG. 1A, an organic BARC (bottom anti-reflecting coating) material 160 is dispersed above and between cells 170 of the semiconductor device 100. Due to the differing geometries of the cells 170 (varying heights, thicknesses, etc.), and their varied distribution on the semiconductor device 100, the organic material 160 may have different thicknesses at different areas of the semiconductor device 100.

FIG. 1B illustrates the exemplary semiconductor device 100 following a conventional etching step.

In a conventional charge trap semiconductor device preparation method, a uniform plasma etch is performed to remove a thin layer of the organic material 160 in order to expose the first oxide layer 152 of the charge trap layer 150 at each of the cells 170. However, because of the non-uniform thickness of the organic BARC material 160, the conventional method can cause numerous problems. For example, as shown in FIG. 1B, the wing height 171a at one location of the semiconductor device 100 may be different from a wing height 171b at another location of the semiconductor device 100. As a result, the etching may not he able to fully expose the first oxide layer 152 at each of the cells 170. For example, many of the cells 170 to the left of the break 101 still have material of the silicon rich nitride layer 154 disposed over the first oxide layer 152, preventing the first oxide layer 152 from properly being exposed at those locations.

These manufacturing errors that result from the conventional manufacturing method can produce unreliable and/or low-performance charge trap semiconductor devices.

### BRIEF DESCRIPTION OF THE DRAWINGS/FIGURES

Embodiments are described herein with reference to the accompanying drawings. In the drawings, like reference numbers generally indicate identical or functionally similar elements. Additionally, generally, the left most digit(s) of a reference number identifies the drawing in which the reference number first appears.

FIG. 1A illustrates a side view of an exemplary semiconductor device prior to charge trap separation;

FIG. 1B illustrates a side view of the semiconductor device of FIG. 1A after a conventional etching step;

FIGS. 2A-2D are side views illustrating formation of an exemplary semiconductor device according to an embodiment;

FIG. 3 is a flowchart of an exemplary method for forming a charge trap semiconductor device having substantially uniform wing heights, according to an embodiment; and

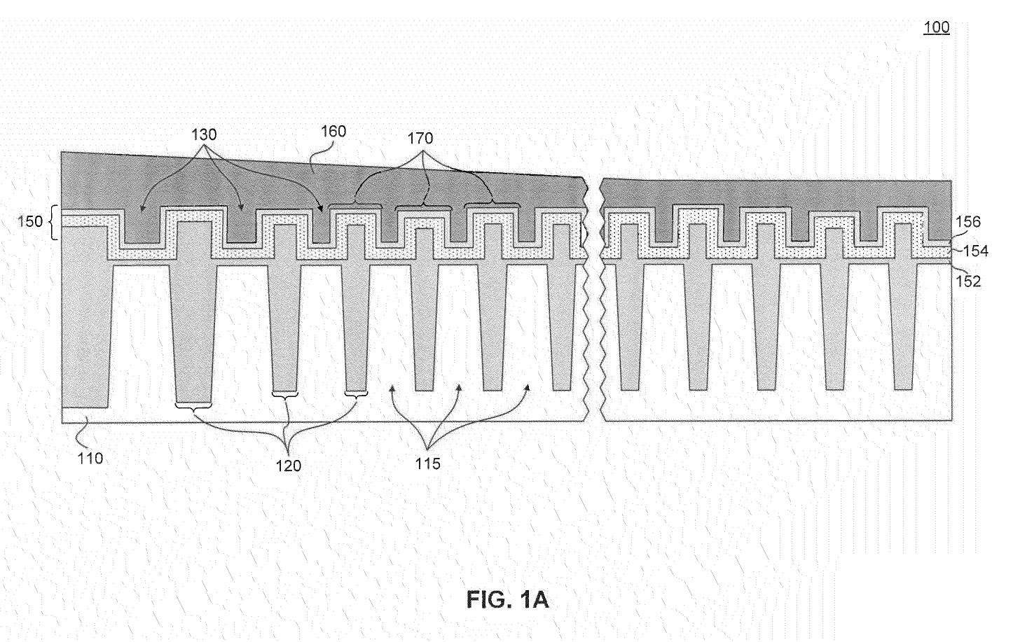

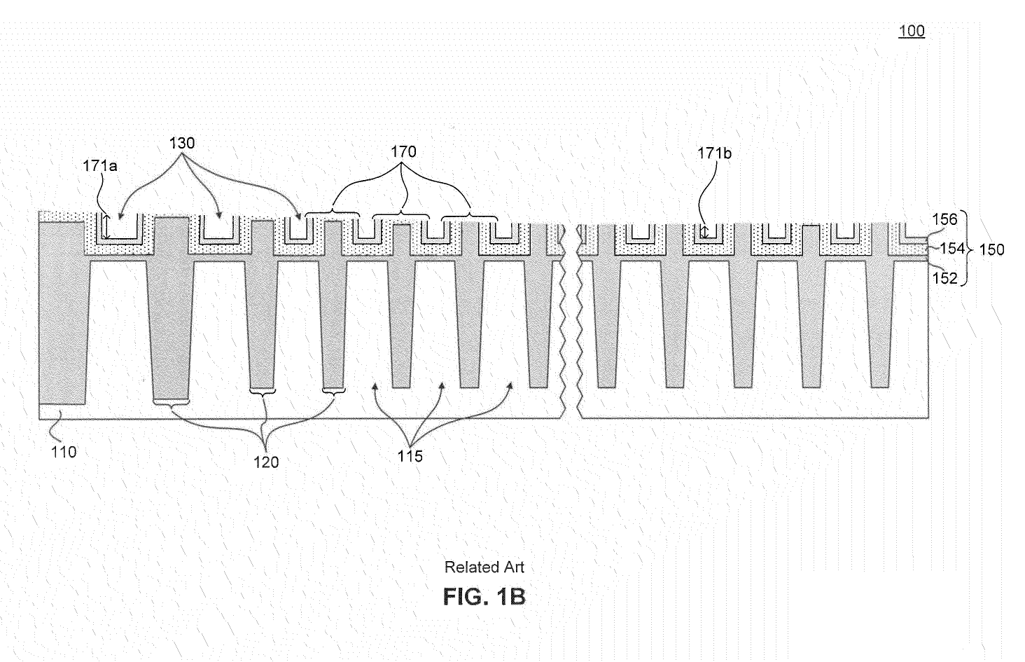

FIG, 4 illustrates a block diagram of an exemplary apparatus for forming a charge trap semiconductor device with substantially uniform wing heights, according to an embodiment.

### DETAILED DESCRIPTION

The following Detailed Description refers to accompanying drawings to illustrate exemplary embodiments consistent with the disclosure. References in the Detailed Description to “one exemplary embodiment,” “an exemplary embodiment,” “an example exemplary embodiment,” etc., indicate that the exemplary embodiment described may include a particular feature, structure, or characteristic, but every exemplary embodiment may not necessarily include the particular feature, structure, or characteristic. Moreover, such phrases are not necessarily referring to the same exemplary embodiment. Further, when a particular feature, structure, or characteristic is described in connection with an exemplary embodiment, it is within the knowledge of those skilled in the relevant art(s) to affect such feature, structure, or characteristic in connection with other exemplary embodiments whether or not explicitly described.

The exemplary embodiments described herein are provided for illustrative purposes, and are not limiting. Other exemplary embodiments are possible, and modifications may be made to the exemplary embodiments within the spirit and scope of the disclosure. Therefore, the Detailed Description is not meant to limit the invention. Rather, the scope of the invention is defined only in accordance with the following claims and their equivalents.

Method embodiments may be implemented in hardware (e.g., circuits), firmware, software, or any combination thereof. Method embodiments may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should he appreciated that such descriptions are merely for convenience and that such actions in fact results from computing devices, processors, controllers, or other devices executing the firmware, software, routines, instructions, etc. Further, any of the implementation variations may be carried out by a general purpose computer.

The following Detailed Description of the exemplary embodiments will so fully reveal the general nature of the invention that others can, by applying knowledge of those skilled in relevant art(s), readily modify and/or adapt for various applications such exemplary embodiments, without undue experimentation, without departing from the spirit and scope of the disclosure. Therefore, such adaptations and modifications are intended to be within the meaning and plurality of equivalents of the exemplary embodiments based upon the teaching and guidance presented herein. It is to be understood that the phraseology or terminology herein is for the purpose of description and not of limitation, such that the terminology or phraseology of the present specification is to be interpreted by those skilled in relevant art(s) in light of the teachings herein.

Those skilled in the relevant art(s) will recognize that this description may be applicable to many various semiconductor devices, and should not be limited to flash memory devices, or any other particular type of semiconductor devices.

### An Exemplary Semiconductor Device

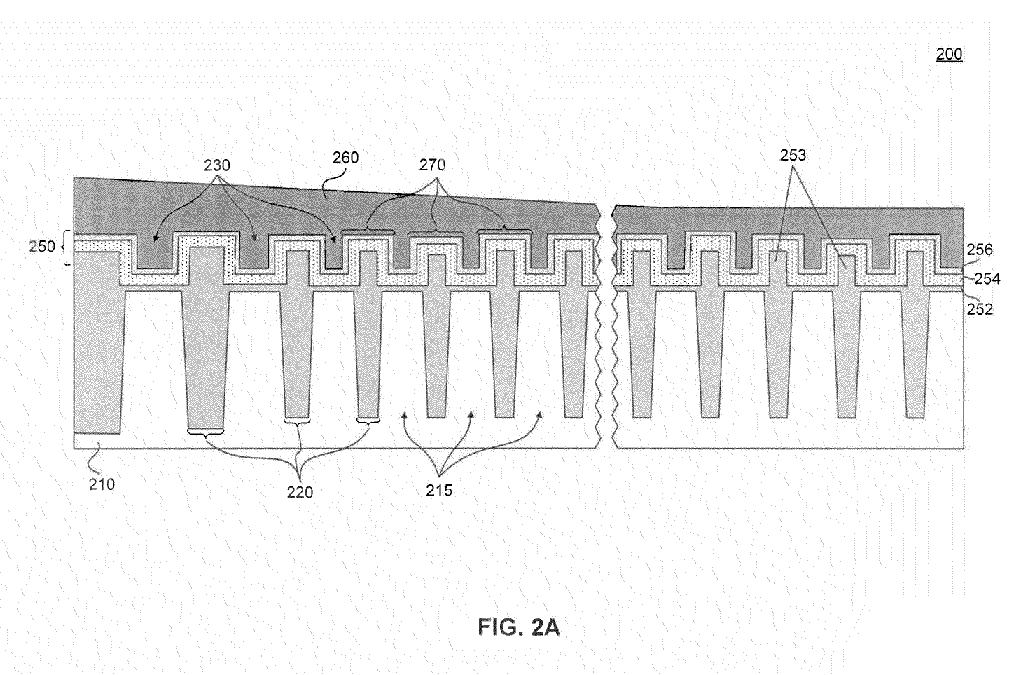

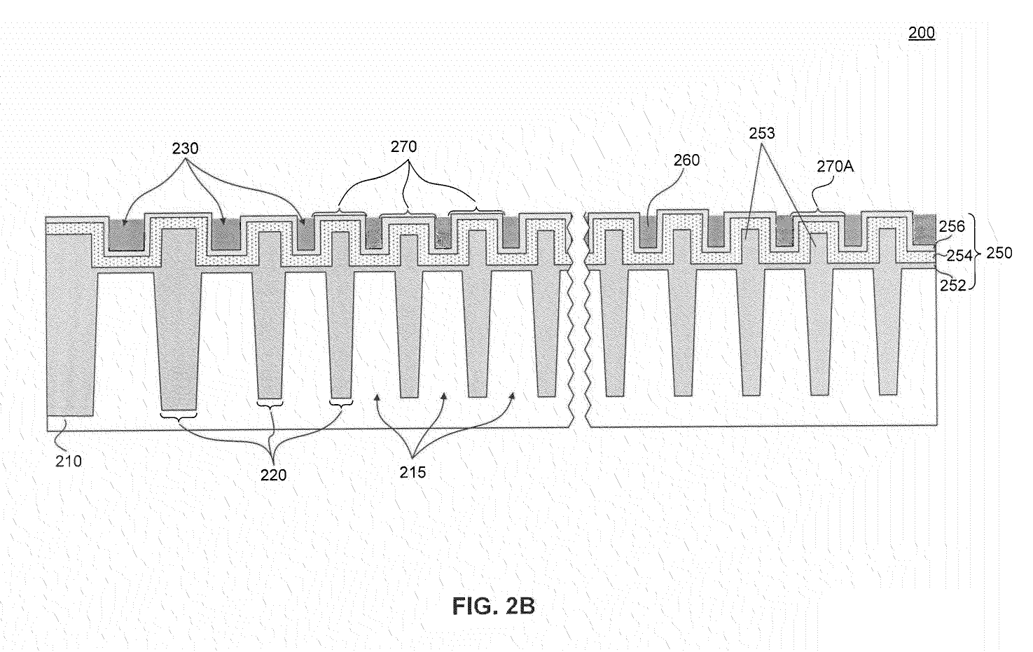

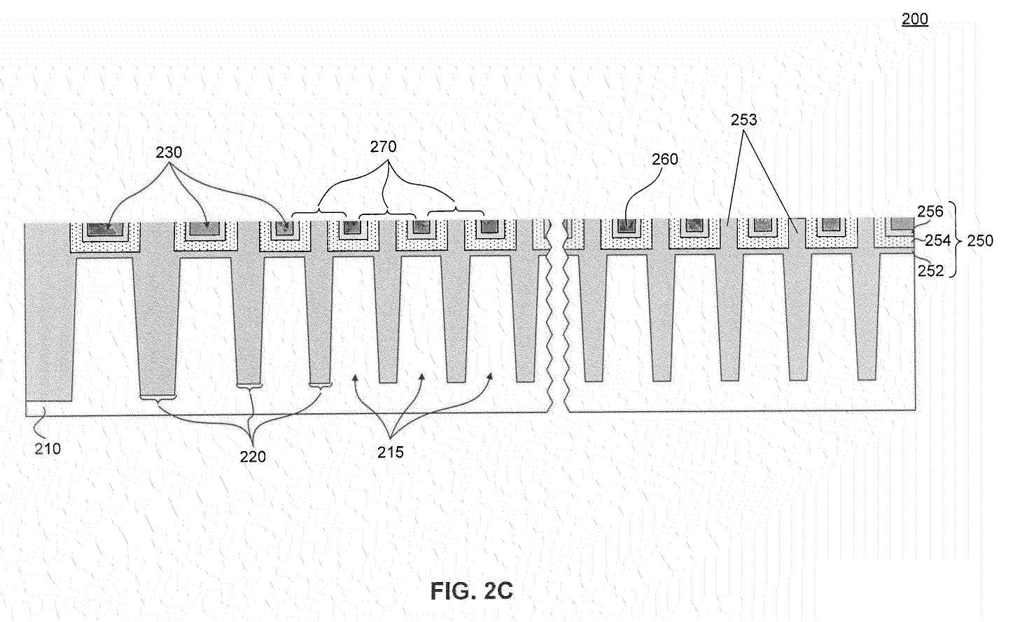

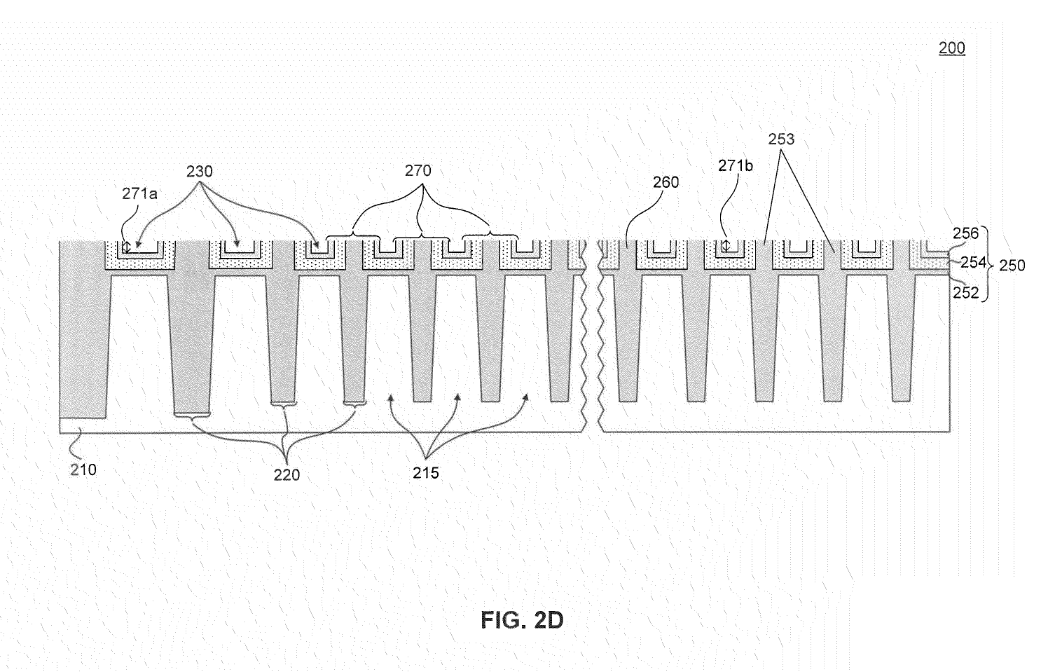

FIG. 2.A illustrates a side view of an exemplary semiconductor device 200 prior to charge trap separation according to an embodiment. Charge trap separation occurs after the charge trap layers 250, which begin as continuous across the semiconductor device 200, are etched to be discontinuous and separate from one another, as shown for example in FIG. 2C.

Referring now to FIG. 2A, the semiconductor device 200 includes a bulk semiconductor substrate 210 that includes a plurality of source/drain regions 215 extending vertically from a base of the substrate 210. Adjacent vertically-extending source/drain regions 215 define isolation trenches 220 therebetween.

Charge trap layers 250 are formed over a top surface of the substrate 210. In an embodiment, the charge trap layers 250 include a first oxide layer 252 that extends into the isolation trenches 220, and which covers a top surface of the substrate 210. The first oxide layer 252 includes substantially rectangular protrusions 253 that extend above the isolation trenches 220. In an embodiment, the charge trap layers 250 further include a silicon rich nitride layer 254 uniformly formed over the first oxide layer 252, as well as a second oxide layer uniformly formed over the silicon rich nitride layer 254. Each of the rectangular protrusions 253 of the combined first oxide layer 252, silicon rich nitride layer 254 and second oxide layer 256 define a cell 270. These cells 270 may be distributed over the substrate at varying intervals and with varying widths and heights (as shown in FIG. 2A).

An organic BARC material 260 is formed over an upper surface of the semiconductor device 200. Due to varying distributions and/or geometries of the cells 270, the organic BARC material 260 may have a non-uniform thickness. For example, the exemplary BARC material 260 illustrated in FIG. 2A has a greater thickness near a left edge than near a right edge of the semiconductor device 200.

FIG. 2B illustrates a side view of the exemplary semiconductor device 200 after a next step in the exemplary charge trap separation method, according to an embodiment.

According to an embodiment, in this step, a selective Chemical Mechanical Polishing (CMP) is performed on the organic BARC material 260. The CMP is performed so as to reduce the thickness of the organic BARC material 260 to be sufficiently small so as not to extend above any of the protruding cells 270. In the example of FIG. 2B, the organic BARC material 260 is nearly the same height as the shortest cell 270A and is slightly smaller in height than each of the remaining cells 270. In an embodiment, the organic material 260 is taller in height than at least one of the cells 270 after the CMP step.

Thus, as a result of this CMP step, and due to the high selectivity of the CMP between the organic BARE material 260 and the charge trap layer 250, the height of the BARC material 260 can be made to be substantially uniform and contained only within cell separation gaps 230 between adjacent cells 270. In other words, the organic BARC material 260 can be removed from the top of the semiconductor device 200 without removing the charge trap layer 250.

FIG. 2C illustrates a side view of the exemplary semiconductor device 200 of FIG. 2B, shown after a subsequent step in the charge trap separation process according to an embodiment.

After the CMP step has been performed, and the organic BARC material 260 has been sufficiently removed to expose the upper surface of the cells 270, a plasma etch is uniformly applied. The plasma etch removes both organic BARC material 260 and charge trap layer 250. This creates a substantially flat upper surface of the semiconductor device 200. In addition, the partial removal of the charge trap layer 250 removes the second oxide layer 256 and the silicon rich nitride layer 254 that exist on top of the cells 270, thereby forming charge trap separation whereby the charge trap layer 250 becomes separated by each of the cells 270. The etch may also remove to portion of the first oxide layer 252 at the cells 270.

As a result of this plasma etch, each of the cells 270 has a substantially uniform wing height. In other words, a height of each of the cells 270 is substantially the same. Consequently, a more stable and accurate semiconductor device 200 is achieved compared to the one manufactured by the conventional manufacturing.

FIG. 2D illustrates a side view of the exemplary semiconductor device 200 of FIG. 2C, shown after a subsequent step in the charge trap separation process.

After the semiconductor device 200 has been etched to a substantially uniform wing height 271, the organic material 260 located within the cell separation gaps 230 is removed using a plasma strip.

In summary, using the above-described method, a semiconductor device 200 can be manufactured with greater yield and better performance resulting from having substantially uniform wing heights among its many cells 270. Consequently, in addition to other advantages, device longevity is increased while manufacturing costs decrease.

### Exemplary Method For Forming Charge Trap Separation in a Semiconductor Device With Substantially Uniform Wing Height

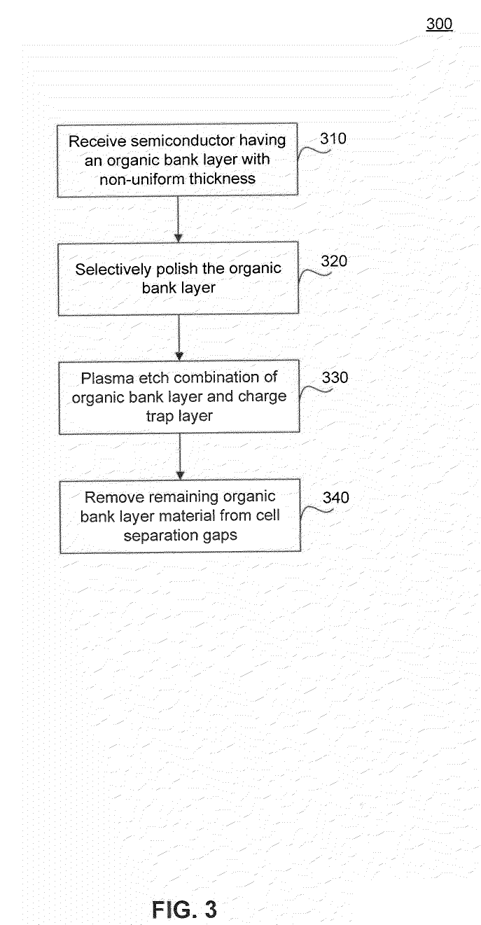

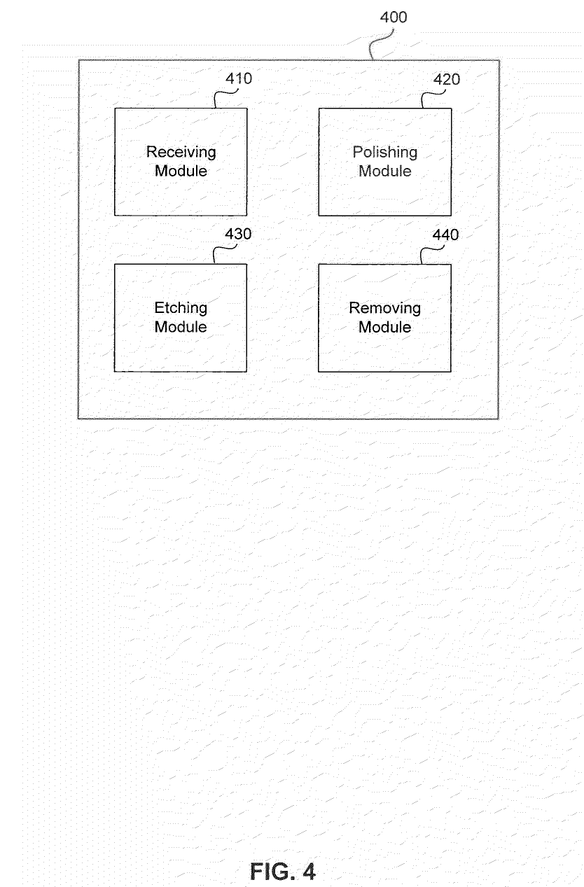

FIG. 3 illustrates a flowchart 300 of a method for forming charge trap separation in a flash memory semiconductor device while maintaining substantially uniform wing heights among various cells, according to an embodiment. For illustration purposes, flowchart 300 is described with continued reference to FIGS. 2A-2D, but method 300 is not limited to this example.

In step 310, referring to FIG. 2A, a semiconductor device 200 is provided with an organic BARC layer 260 formed over a plurality of cells 270. The organic BARC layer 260 may, or may not, have uniform thickness.

In step 320, referring to FIG. 2B, the organic BARC layer 260 is then selectively polished using a CMP procedure. The organic BARC layer 260 is polished to have a substantially uniform height and/or flat upper surface. in an embodiment, the organic BARC layer 260 is polished so as to have a thickness that is not greater than a thickness of any of the cells 270.

In step 330, referring to FIG. 2C, once the organic BARC layer 260 has been polished, a plasma etch can be performed to etch one or both of the organic BARC layer 260 and the charge trap layer 250 (ONO layer) of the cells 270. The etch is performed so as to expose a lower first oxide layer 252 at each of the cells 270 by etching away the organic BARC layer 260, upper second oxide layer 256, and silicon rich nitride layer 254 that may be covering the first oxide layer 252 at the cells 270.

In step 340, referring to FIG. 2D, once etched, the remaining organic BARC material 260 is removed from cell separation gaps 230 using a plasma strip process or other similar process.

Those skilled in the relevant art(s) will recognize that the above method can additionally or alternatively include any of the steps or substeps described above with respect to FIGS. 2A-2D, as well as any of their modifications. Further, the above description of the exemplary method should not be construed to limit the description of the method depicted in FIGS. 2A-2D and described above.

### Exemplary Apparatus For Forming Charge Trap Separation in a Semiconductor Device With Substantially Uniform Wing Height

FIG. 4 illustrates a block diagram of an exemplary apparatus 400 for forming a charge trap semiconductor device with substantially uniform wing heights, according to an embodiment. The apparatus 400 includes a receiving module 410, a polishing module 420, an etching module 430, and a removing module 440. For illustration purposes, apparatus 400 is described with continued reference to FIGS. 2A-2D.

The receiving module 410 is configured to receive a semiconductor device 200 that has an organic BARC layer 260 formed over a plurality of cells 270. The organic BARC layer 260 may, or may not, have uniform thickness. The polishing module 420 is configured to selectively polish the organic BARC layer 260 using a CMP procedure. The polishing module 420 polishes the organic BARC layer 260 to have a substantially uniform height and/or flat upper surface. In an embodiment, the polishing module 420 polishes the organic BARC layer 260 so as to have a thickness that is not greater than a thickness of any of the cells 270.

Once the organic BARC layer 260 has been polished, the etching module 430 performs a plasma etch on one or both of the organic BARE layer 260 and the charge trap layer 250 of the cells 270. The etching module 430 is configured to etch away the organic BARC layer 260, upper second oxide layer 256, and silicon rich nitride layer 254 that may be covering the first oxide layer 252 at the cells 270 in order to expose the lower first oxide layer 252 at each of the cells 270.

Once etched, the removing module 440 removes the remaining organic BARC material 260 from the cell separation gaps 230 using a plasma strip process or other similar process.

Those skilled in the relevant art(s) will recognize that the above apparatus 400 can additionally or alternatively be configured to perform any of the steps or substeps described above with respect to FIGS. 2A-2D, as well as any of their modifications. Further, the above description of the exemplary apparatus 400 should not be construed to limit the description of the method depicted in FIGS. 2A-2D.

### CONCLUSION

It is to be appreciated that the Detailed Description section, and not the Abstract section, is intended to be used to interpret the claims. The Abstract section may set forth one or more, but not all exemplary embodiments, and thus, is not intended to limit the disclosure and the appended claims in any way.

Embodiments of the invention have been described above with the aid of functional building blocks illustrating the implementation of specified functions and relationships thereof. The boundaries of these functional building blocks have been arbitrarily defined herein for the convenience of the description. Alternate boundaries may be defined so long as the specified functions and relationships thereof are appropriately performed.

It will be apparent to those skilled in the relevant art(s) that various changes in form and detail can be made therein without departing from the spirit and scope of the disclosure. Thus, the invention should not be limited by any of the above-described exemplary embodiments, but should be defined only in accordance with the following claims and their equivalents.

What is clamed is:

1. A method of forming a semiconductor device, the method comprising:
forming an organic BARC layer over a plurality of cells, the BARC layer having a non-uniform thickness;
selectively removing a portion of the organic BARC layer so as to obtain a substantially flat upper surface of the organic BARC layer;
etching the organic BARC layer and the cells; and
removing remaining organic BARC layer material.

2. The method of claim 1, wherein the organic BARC layer that results from the selectively removing, has a thickness that is no greater than any of the plurality of cells.

3. The method of claim 1, wherein the organic BARC layer that results from the selectively removing has a thickness that is greater than each of the plurality of cells.

4. The method of claim 1, wherein each of the cells includes a first oxide layer, a silicon-rich nitride layer formed over the first oxide layer, and a second oxide layer formed over the silicon-rich nitride layer.

5. The method of claim 4, wherein the etching removes the second organic layer and the silicon-rich nitride layer from above a protruding portion of the first oxide layer at each of the cells.

6. The method of claim 4, wherein the etching exposes the first oxide layer at each of the cells.

7. The method of claim 1, wherein the removing comprises removing organic BARC layer material from cell separation gaps between adjacent cells.

8. A method of forming charge trap separation in a semiconductor device, the semiconductor device having a cell that includes a protruding first oxide layer, a silicon-rich nitride layer formed on the first oxide layer, and a second oxide layer formed on the silicon-rich nitride layer, the method comprising:
forming an organic BARC material over the cell;
removing a portion of the organic BARC material to provide the organic BARC material with an upper surface that is substantially flat; and
etching a combination of the organic BARE material and at least a portion of the cell.

9. The method of claim 8, wherein the removing removes the portion of the organic BARC material such that the upper surface of the organic BARC material is disposed over the cell.

10. The method of claim 8, wherein the removing removes the portion of the organic BARC material such that the upper surface of the organic BARC material is disposed substantially even with an upper surface of the second oxide layer of the cell.

11. The method of claim 8, wherein the removing removes the portion of the organic BARC material such that the upper surface of the organic BARC material is disposed below an upper surface of the second oxide layer of the cell.

12. The method of claim 8, wherein the etching exposes the first oxide layer.

13. The method of claim 12, wherein etching removes any BARC material, the second oxide layer, and the silicon-rich nitride layer, that are disposed over the protruding first oxide layer.

14. The method of claim 8, wherein the etching removes a portion of the protruding first oxide layer.

15. An apparatus, comprising:
a receiving module configured to receiving a semiconductor device having an organic BARC layer formed over a plurality of cells, the BARC layer having a non-uniform thickness;
a polishing module configured to selectively remove a portion of the organic BARC layer so as to make an upper surface of the organic BARC layer be substantially flat;
an etching module configured to etch the organic BARC layer and the cells; and
a removing module configured to remove remaining organic BARC layer material.

16. The apparatus of claim 15, wherein the polishing module is configured to cause the organic BARC layer to have a thickness that is no greater than any of the cells.

17. The apparatus of claim 15, wherein each of the cells includes a first oxide layer, a silicon-rich nitride layer formed over the first oxide layer, and a second oxide layer formed over the silicon-rich nitride layer.

18. The apparatus of claim 17, wherein the etching module is configured to remove the second organic layer and the silicon-rich nitride layer from above a protruding portion of the first oxide layer at each of the cells.

19. The apparatus of claim 17, wherein the etching module is configured to expose the first oxide layer at each of the cells.

20. The apparatus of claim 17, wherein the removing module is configured to remove comprises removing organic BARC layer material from cell separation gaps between adjacent cells.
